(19) United States
(12) Patent Application Publication
(10) Pub. No.: US 2024/0355922 A1
(43) Pub. Date: Oct. 24, 2024

(54) SEMICONDUCTOR DEVICE, POWER CONVERSION APPARATUS, AND METHOD OF MANUFACTURING SEMICONDUCTOR DEVICE

(71) Applicant: Mitsubishi Electric Corporation, Tokyo (JP)

(72) Inventors: Katsutoshi SUGAWARA, Tokyo (JP); Kotaro KAWAHARA, Tokyo (JP); Akifumi IIJIMA, Tokyo (JP); Shiro HINO, Tokyo (JP); Katsuhiro FUJIYOSHI, Tokyo (JP)

(73) Assignee: Mitsubishi Electric Corporation, Tokyo (JP)

(21) Appl. No.: 18/413,662

(22) Filed: Jan. 16, 2024

(30) Foreign Application Priority Data
Apr. 20, 2023 (JP) 2023-069138

(51) Int. Cl. H01L 29/78; H01L 21/04; H01L 29/06; H01L 29/08; H01L 29/16; H01L 29/66; H02P 27/08

(52) U.S. Cl. CPC H01L 29/7806; H01L 21/046; H01L 29/063; H01L 29/086; H01L 29/1608; H01L 29/66068; H01L 29/7813; H02P 27/08

(57) ABSTRACT

A semiconductor device includes: a drift layer of a first conductivity type; well layers of a second conductivity type; a source layer of a first conductivity type; a gate electrode; an interlayer insulating film; and a source electrode, in which a plurality of body diodes constituted by the well layer and the drift layer at positions not overlapping with the gate electrode in plan view include a first operation portion that operates at a first body diode operation voltage and a plurality of second operation portions that operate at a second body diode operation voltage lower than the first body diode operation voltage.

### BACKGROUND OF THE INVENTION

### Field of the Invention

The technology disclosed in the present specification relates to a semiconductor technology.

### Description of the Background Art

In power electronics devices, insulated gate semiconductor devices such as insulated gate bipolar transistors (i.e., IGBT) or metal-oxide-semiconductor field-effect transistors (i.e., MOSFET) are widely used as switching elements for controlling power supply to a load such as a motor.

On the other hand, as a next-generation switching element, a MOSFET, an IGBT, or the like using a wide bandgap semiconductor such as silicon carbide (SiC) has attracted attention, and application to a technical field handling a high voltage of about 1 kV or more is expected.

In addition to SiC, examples of the wide bandgap semiconductor include gallium nitride (GaN)-based materials and diamond.

A technique related to a Schottky barrier diode (i.e., SBD) built-in MOSFET in which a body diode (BD) in a direction opposite to the MOSFET is parasitic in the SiC-MOSFET and reverse energization is performed without operating the BD is known (see, for example, WO 2018/139556 A).

The SBD built-in MOSFET is required not to be broken for a certain period of time when a large current called a surge current flows. This tolerance for not being broken for a certain period of time is referred to as an I2t tolerance. However, in a case where the SBD is built in to make it difficult to energize the body diode, unipolar energization capability is improved, but the I2t tolerance is affected, and the I2t tolerance may be lowered.

### SUMMARY

The technology disclosed in the present specification is a technology for suppressing a decrease in the I2t tolerance in a semiconductor device having an SBD built therein.

A semiconductor device according to a first aspect of the technology disclosed in the present specification includes: a drift layer of a first conductivity type; a plurality of well layers of a second conductivity type partially formed on a surface layer of the drift layer; a source layer of a first conductivity type partially formed on a surface layer of each of the well layers; a gate electrode that is in contact with the well layer sandwiched between the drift layer and the source layer via a gate insulating film; an interlayer insulating film provided to cover the gate electrode; and a source electrode provided to cover the interlayer insulating film, the well layer, and the source layer, in which a plurality of body diodes constituted by the well layer and the drift layer at positions not overlapping with the gate electrode in plan view include a first operation portion that operates at a first body diode operation voltage and a plurality of second operation portions that operate at a second body diode operation voltage lower than the first body diode operation voltage.

According to at least the first aspect of the technology disclosed in the present specification, it is possible to suppress a decrease in the I2t tolerance.

Further, objects, features, aspects, and advantages relating to the technology disclosed in the present specification will be more apparent from the following detailed description and the accompanying drawings.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view of a semiconductor device, which is an SBD built-in MOSFET using SiC, as viewed from above;

FIGS. 2 and 3 are plan views each mainly illustrating an example of a configuration of a silicon carbide semiconductor portion in the plan view of FIG. 1;

FIG. 4 is a cross-sectional view illustrating an example of a structure of the SBD built-in MOSFET in an active region of FIG. 2 or 3;

FIG. 5 is a cross-sectional view illustrating an example of a structure of a silicon carbide semiconductor device according to the preferred embodiment;

FIGS. 6 and 7 are cross-sectional views each illustrating another example of the structure of the silicon carbide semiconductor device according to the preferred embodiment;

FIG. 8 is a plan view mainly illustrating an example of the configuration of the silicon carbide semiconductor portion in the top view of FIG. 1;

FIGS. 9 to 11 are cross-sectional views each illustrating another example of the structure of the silicon carbide semiconductor device according to the preferred embodiment;

FIG. 12 is a diagram illustrating an example of gate voltage-drain current characteristics of the SBD built-in MOSFET;

FIG. 13 is a diagram illustrating an example of drain voltage-drain current characteristics of the SBD built-in MOSFET;

FIGS. 14 to 20 are views each illustrating an example of a method of manufacturing a silicon carbide semiconductor device according to a preferred embodiment; and

FIG. 21 is a block diagram illustrating a configuration of a power conversion system to which the power conversion apparatus according to the preferred embodiment is applied.

### DESCRIPTION OF THE PREFERRED EMBODIMENTS

Hereinafter, preferred embodiments will be described with reference to the accompanying drawings. In the following preferred embodiments, detailed features and the like are also shown for the description of the technology, but they are merely examples, and not all of them are necessarily essential features for enabling the preferred embodiments to be carried out.

The drawings are schematically illustrated, and omission of a configuration, simplification of a configuration, or the like is appropriately made in the drawings for convenience of description. In addition, the mutual relationship of sizes and positions of configurations and the like illustrated in different drawings is not necessarily accurately described, and can be appropriately changed. In addition, hatching may be applied to a drawing such as a plan view that is not a cross-sectional view in order to facilitate understanding of the contents of the preferred embodiments.

Furthermore, in the following description, similar components are denoted by the same reference numerals, and names and functions thereof are also similar. Therefore, detailed description thereof may be omitted in order to avoid duplication.

In addition, in the description described in the present specification, when a certain component is described as “comprising”, “including”, “having”, or the like, the expression is not an exclusive expression excluding the presence of other components unless otherwise specified.

In addition, in the description described in the present specification, even if ordinal numbers such as “first” or “second” are used, these terms are used for convenience to facilitate understanding of the contents of the preferred embodiments, and the contents of the preferred embodiments are not limited to the order or the like that can be caused by these ordinal numbers.

Furthermore, in the description described in the present specification, even if terms meaning specific positions or directions such as “upper”, “lower”, “left”, “right”, “side”, “bottom”, “front”, or “back” are used, these terms are used for convenience to facilitate understanding of the contents of the preferred embodiments, and are not related to the positions or directions when the preferred embodiments are actually implemented.

Furthermore, in the description described in the present specification, the description of “the upper surface of . . . ”, “the lower surface of . . . ”, or the like includes a state in which another component is formed on the upper surface or the lower surface of the target component in addition to the upper surface itself or the lower surface itself of the target component. That is, for example, when it is described as “B provided on the upper surface of A”, it does not prevent another component “C” from being interposed between A and B.

### First Preferred Embodiment

In the following description, n and p represent a conductivity type of a semiconductor, and a first conductivity type is described as an n type and a second conductivity type is described as a p type. However, the first conductivity type may be the p type, and the second conductivity type may be the n type.

In addition, n′ indicates that the impurity concentration is lower than n, and n⁺ indicates that the impurity concentration is higher than n. Similarly, p⁻ indicates that the impurity concentration is lower than p, and p⁺ indicates that the impurity concentration is higher than p.

Hereinafter, preferred embodiments will be described with reference to the accompanying drawings. Note that the drawings are schematically illustrated, and the mutual relationship between the sizes and positions of images illustrated in different drawings is not necessarily accurately described, and can be appropriately changed. In addition, in the following description, similar components are denoted by the same reference numerals, and names and functions thereof are also similar. Therefore, a detailed description thereof may be omitted.

Hereinafter, a semiconductor device according to the present preferred embodiment will be described. For convenience of description, first, a technology related to a configuration of an SBD built-in MOSFET known by the inventor will be described.

### <Configuration of Semiconductor Device>

SiC has many crystal polymorphs. The crystal polymorph is based on a difference in atomic arrangement constituting the crystal, and SiC crystals having different crystal polymorphs exhibit different physical properties.

In general, a semiconductor element whose crystal polymorph is 4H—SiC is used as a semiconductor element for power control. However, it is difficult to constitute a SiC crystal with only one crystal type, and other crystal types may be mixed during crystal growth. This is called a stacking fault.

A pn diode called a body diode is parasitic between a drain and a source of a MOSFET for power control, and can perform an operation in a reverse direction of applying a positive voltage to a source electrode in addition to an operation in a forward direction of applying a positive voltage to a drain electrode.

By using such a body diode, the number of reflux diodes arranged in parallel to the MOSFET can be reduced, and the number of elements of the circuit can be reduced. The MOSFET is a unipolar element in which only electrons or holes flow, whereas the pn diode is a bipolar element in which both of them flow simultaneously. It is known that when SiC performs bipolar operation, the stacking fault is expanded by recombination energy of electron-hole pairs.

Since the stacking fault in the 4H—SiC crystal behaves as a high resistor, expansion of the crystal defect leads to an increase in element resistance. Therefore, when the MOSFET and the SBD are arranged in parallel, it is necessary to design the SBD such that the body diode of the MOSFET does not operate within the range of the current to be used, in other words, the generated voltage does not reach the rising voltage of the body diode.

Therefore, an SBD built-in MOSFET technology has been developed in which an SBD is built in a SiC-MOSFET and a reverse current flows in the SBD instead of a body diode.

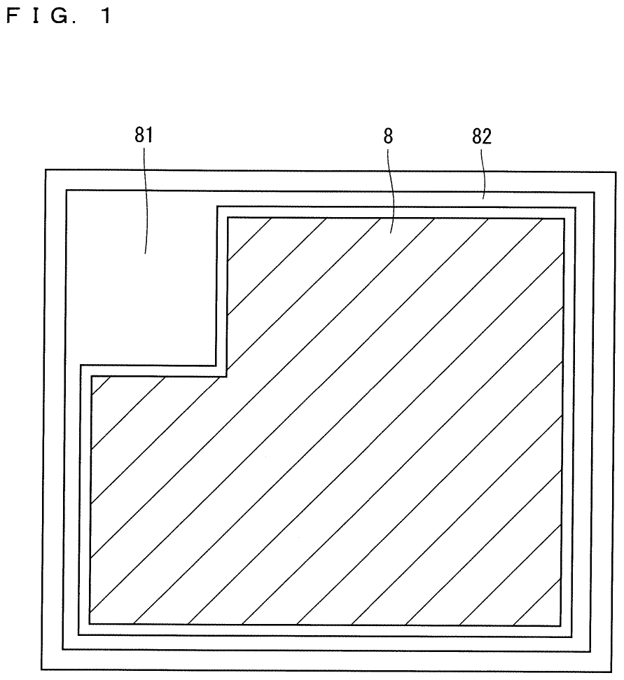

FIG. 1 is a plan view of a semiconductor device, which is an SBD built-in MOSFET using SiC, as viewed from above. In FIG. 1, a gate pad 81 is formed on a part of an upper surface of the SBD built-in MOSFET, and a source electrode 8 is formed adjacent to the gate pad 81. A gate wiring 82 is formed so as to extend from the gate pad 81.

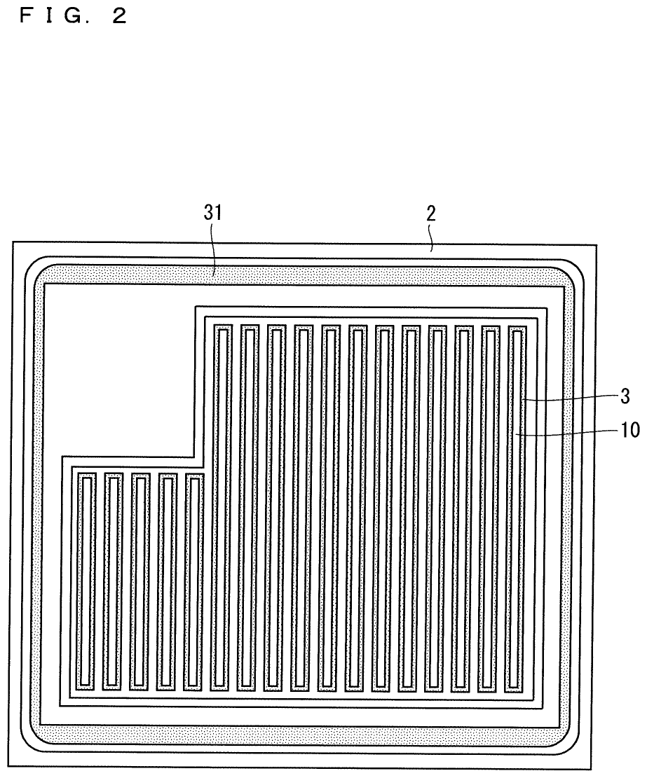

FIG. 2 is a plan view mainly illustrating an example of a configuration of a silicon carbide semiconductor portion in the plan view of FIG. 1. In the semiconductor device illustrated in FIG. 2 as an example, unit cell regions in which MOSFET regions are formed are provided side by side in a stripe shape on both sides of an SBD region, and the semiconductor device is also referred to as a “stripe type”.

In FIG. 2, unit cell regions each including an n-type separation region 10 substantially corresponding to the SBD and a p-type well layer 3 substantially corresponding to the MOSFET are repeatedly arranged in one direction in plan view on the drift layer 2. A region where the SBD built-in MOSFET is formed is referred to as an active region, and a region including a formation region of the gate pad 81 (see FIG. 1) where a p-type well layer 31 and the like are formed on the outer periphery of the active region is referred to as a termination region.

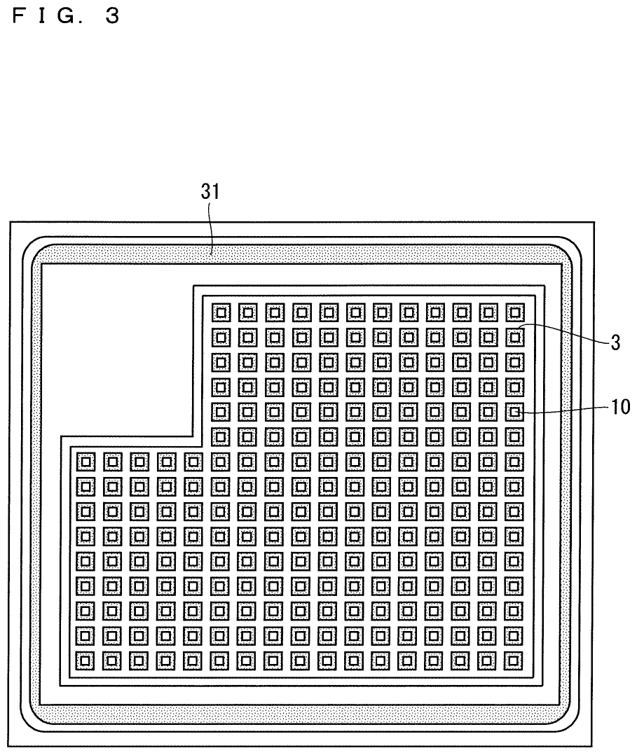

FIG. 3 is a plan view mainly illustrating an example of the configuration of the silicon carbide semiconductor portion in the plan view of FIG. 1. In the semiconductor device illustrated in FIG. 3 as an example, unit cell regions in which a MOSFET region surrounding an SBD region is formed are repeatedly arranged vertically and horizontally in plan view, and the semiconductor device is referred to as “lattice type”.

In FIG. 3, on the drift layer 2, unit cell regions including an n-type separation region 10 substantially corresponding to the SBD and a p-type well layer 3 substantially corresponding to the MOSFET are repeatedly arranged in the vertical and horizontal directions in plan view. A region where the SBD built-in MOSFET is formed is referred to as an active region, and a region including a formation region of the gate pad 81 where the p-type well layer 31 and the like are formed on the outer periphery of the active region is referred to as a termination region.

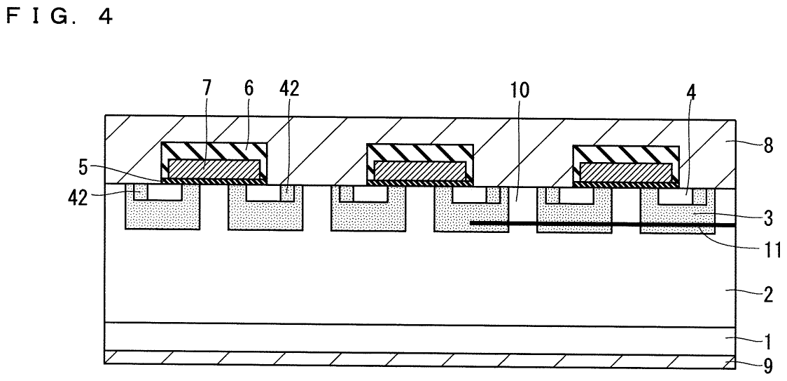

FIG. 4 is a cross-sectional view illustrating an example of a structure of the SBD built-in MOSFET in the active region of FIG. 2 or 3.

As illustrated in FIG. 4 as an example, the SBD built-in MOSFET includes an n-type semiconductor substrate 1, an n-type drift layer 2 formed on an upper surface of the n-type semiconductor substrate 1, a plurality of p-type well layers 3 partially formed on a surface layer of the n-type drift layer 2, an n-type source layer 4 formed on a surface layer of the p-type well layer 3, a p-type contact region 42 partially formed on a surface layer of the p-type well layer 3 and having a higher impurity concentration than the p-type well layer 3, a gate electrode 7 facing an upper surface of the p-type well layer 3 sandwiched between the n-type drift layer 2 and the n-type source layer 4 via a gate insulating film 5, an interlayer insulating film 6 formed to cover an upper surface and a side surface of the gate electrode 7, a source electrode 8 formed to cover the interlayer insulating film 6, the n-type drift layer 2, the p-type well layers 3, the n-type source layers 4, and the p-type contact regions 42, and a drain electrode 9 formed on a lower surface of the n-type semiconductor substrate 1. A region between the p-type well layers 3 at a position not overlapping with the gate electrode 7 in plan view is defined as an n-type separation region 10. In addition, in the case of FIG. 4, a state in which a stacking fault 11 is formed across the plurality of p-type well layers 3 is illustrated.

Here, the SBD is formed by the n-type separation region 10 and the source electrode 8. The body diode is formed of the p-type well layer 3 and the n-type drift layer 2.

Since the SBD is a unipolar element, the SBD does not cause expansion of a stacking fault unlike the body diode. The built-in SBD shares the n-type drift layer 2 with the body diode, unlike the SBD provided outside the MOSFET.

As a result, since the voltage applied to the SBD and the voltage applied to the body diode become equal, the rising voltage of the body diode of the SBD built-in MOSFET becomes larger than that of the body diode parasitic in a normal MOSFET. That is, the SBD built-in MOSFET can flow a larger amount of SBD current than a case where the normal MOSFET and the SBD are arranged in parallel.

When a current surge flows through the SBD, the SBD may generate heat to cause breakdown. A structure called a junction barrier controlled Schottky diode (JBS) in which a pn diode is connected in parallel to an SBD is used to increase the I2t tolerance that is resistance to the current surge.

The SBD in JBS has a low rising voltage, whereas the pn diode in JBS has a high rising voltage. As a result, the SBD is operated during the normal operation, and when a current surge flows, the pn diode is operated to lower the generated voltage, so that breakdown can be prevented. In particular, since the operating voltage of the pn diode decreases at a high temperature, the JBS has a higher I2t tolerance than a normal SBD.

In the SBD built-in MOSFET, the body diode functions similarly to the pn diode of the JBS. That is, when a certain current surge is applied, the body diode operates, the generated voltage decreases, and the current path is switched from the built-in SBD to the body diode.

However, the inventors have found that the histogram of the body diode operation voltage (voltage at which the body diode operates) of the SBD built-in MOSFET has a plurality of peaks, and this is caused by the stacking fault described above.

As illustrated in FIG. 4 as an example, some of the stacking faults 11 have already reached the surface layer of the n-type drift layer 2 at the time point after epitaxial growth of the n-type drift layer 2. Then, by the stacking fault 11, which is the high resistance layer, closing the separation region 10, which is the built-in SBD, the parallel relationship between the body diode and the built-in SBD is locally solved, and the operating voltage of the body diode at that portion decreases.

Then, since electron-hole pairs generated by the operation of the body diode diffuse to the periphery and induce the body diode operation in a chain manner, the region where the body diode operates has a certain area. Since a surge current is concentrated in this region, thermal breakdown occurs at a small current value as a result. In particular, in the case of a module in which a large number of semiconductor chips are connected in parallel, most of the current concentrates on the chip in which the operating voltage of the body diode has decreased, and thus the I2t tolerance as a whole further decreases.

On the other hand, when the case where the stacking fault is included and the case where the stacking fault is not included are compared, it is also found that the former may exhibit a higher I2t tolerance. When the semiconductor chip does not include the stacking fault, the operating voltage of the body diode increases, so that the heat generation amount at the same current value increases, and the I2t tolerance decreases. When the number of stacking faults included in the semiconductor chip is small, the operating voltage of the body diode decreases, but the current density of the stacking fault portion excessively increases, so that the I2t tolerance further decreases. In a case where there are many stacking faults, the body diode operation occurs at a plurality of places, and the current is dispersed, so that it is difficult to reach the current density that causes thermal breakdown, and the I2t tolerance increases. The position or the number of stacking faults appears as variation in the I2t tolerance of the module.

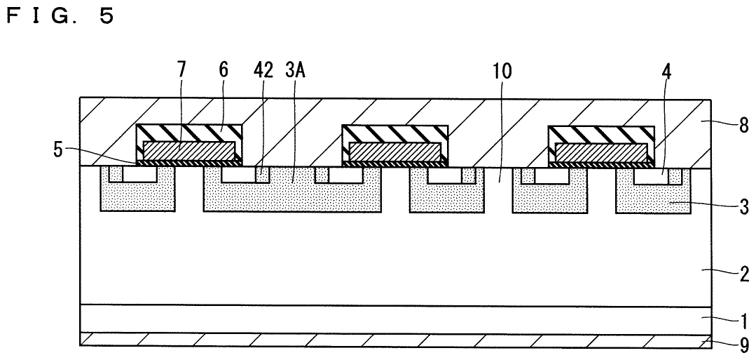

FIG. 5 is a cross-sectional view illustrating an example of a structure of a silicon carbide semiconductor device according to the present preferred embodiment. In the following description, an SBD built-in MOSFET is used as the silicon carbide semiconductor device, but JBS or the like may be used as long as it is an element in which a Schottky junction and a pn junction are connected in parallel.

As illustrated in FIG. 5 as an example, the SBD built-in MOSFET includes an n-type semiconductor substrate 1, an n-type drift layer 2 formed on an upper surface of the n-type semiconductor substrate 1, a plurality of p-type well layers 3 partially formed on a surface layer of the n-type drift layer 2, a p-type well layer 3A partially formed on a surface layer of the n-type drift layer 2, an n-type source layer 4 formed on a surface layer of the p-type well layer 3 and a surface layer of the p-type well layer 3A, a p-type contact region 42 partially formed on a surface layer of the p-type well layer 3 and a surface layer of the p-type well layer 3A and having a higher impurity concentration than the p-type well layer 3, a gate electrode 7 facing an upper surface of the p-type well layer 3 sandwiched between the n-type drift layer 2 and the n-type source layer 4 and an upper surface of the p-type well layer 3A sandwiched between the n-type drift layer 2 and the n-type source layer 4 via a gate insulating film 5, an interlayer insulating film 6 formed to cover an upper surface and a side surface of the gate electrode 7, a source electrode 8 formed to cover the interlayer insulating film 6, the n-type drift layer 2, the p-type well layers 3, the p-type well layer 3A, the n-type source layers 4, and the p-type contact regions 42, and a drain electrode 9 formed on a lower surface of the n-type semiconductor substrate 1. A region between the p-type well layers 3 at a position not overlapping with the gate electrode 7 in plan view is defined as a separation region 10. The contact resistance of the contact region 42 in the surface layer of the p-type well layer 3 is higher than the contact resistance of the contact region 42 in the surface layer of the p-type well layer 3A.

The width of the p-type well layer 3A is formed to be wider than the width of the p-type well layer 3. In addition, the n-type source layers 4 facing the plurality of gate electrodes 7 are formed on the surface layer of the p-type well layer 3A. That is, the p-type well layer 3A is formed so as to fill the separation region 10 between the p-type well layers 3, and functions as a body diode operation structure.

As described above, in the power module in which the SBD built-in MOSFETs are connected in parallel, the I2t tolerance varies depending on the number of stacking faults inherent in the semiconductor chip. In particular, when the number of stacking faults is small, the I2t tolerance is extremely lowered, so that breakage during use is concerned.

In order to solve this problem, a plurality of portions where the body diode operation is caused may be provided in the semiconductor chip. That is, in the silicon carbide semiconductor device according to the present preferred embodiment, in order to lower the body diode operation voltage, a body diode operation structure is provided which is a structure that causes the body diode operation.

The body diode operation structure only needs to satisfy either or both of the rising voltage of the body diode being lower than the portion having the stacking fault and the linear resistance of the body diode being lower.

First, in order to lower the rising voltage of the body diode, the voltage drop of the SBD portion may be reduced.

For example, in the p-type well layer 3A illustrated in FIG. 5 as an example, the separation region 10 is closed with a p-type impurity layer. With this, the parallel state of the Schottky junction and the pn junction is released, so that the body diode operation voltage at this portion decreases. That is, a second operation portion having the body diode operation structure has a lower body diode operation voltage than a first operation portion which is a normal portion having no body diode operation structure.

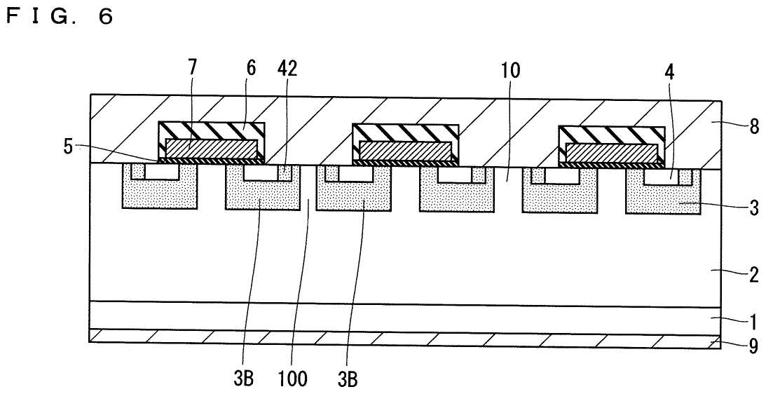

FIG. 6 is a cross-sectional view illustrating another example of the structure of the silicon carbide semiconductor device according to the present preferred embodiment.

As illustrated in FIG. 6 as an example, the SBD built-in MOSFET includes an n-type semiconductor substrate 1, an n-type drift layer 2 formed on an upper surface of the n-type semiconductor substrate 1, a plurality of p-type well layers 3 partially formed on a surface layer of the n-type drift layer 2, a p-type well layer 3B partially formed on a surface layer of the n-type drift layer 2, an n-type source layer 4 formed on a surface layer of the p-type well layer 3 and a surface layer of the p-type well layer 3B, a p-type contact region 42 partially formed on a surface layer of the p-type well layer 3 and a surface layer of the p-type well layer 3B and having a higher impurity concentration than the p-type well layer 3, a gate electrode 7 facing an upper surface of the p-type well layer 3 sandwiched between the n-type drift layer 2 and the n-type source layer 4 and an upper surface of the p-type well layer 3B sandwiched between the n-type drift layer 2 and the n-type source layer 4 via a gate insulating film 5, an interlayer insulating film 6 formed to cover an upper surface and a side surface of the gate electrode 7, a source electrode 8 formed to cover the interlayer insulating film 6, the n-type drift layer 2, the p-type well layers 3, the p-type well layer 3B, the n-type source layers 4, and the p-type contact regions 42, and a drain electrode 9 formed on a lower surface of the n-type semiconductor substrate 1. A region between the p-type well layers 3 at a position not overlapping with the gate electrode 7 in plan view is defined as a separation region 10. A region between the p-type well layers 3B is defined as a separation region 100.

The width of the p-type well layer 3B is formed to be wider than the width of the p-type well layer 3. However, the width of the p-type well layer 3B may be equal to the width of the p-type well layer 3. In addition, the interval between the p-type well layers 3B is narrower than the interval between the p-type well layers 3. That is, the separation region 100 at a position not overlapping with the gate electrode 7 formed of the plurality of p-type well layers 3B in plan view is narrower than the separation region 10, and the separation region 100 functions as a body diode operation structure having a body diode operation voltage lower than that of the body diode operation formed of the well layer 3 and the drift layer 2 at the separation region 10. Here, the difference in the work function between the drift layer 2 and the source electrode 8 in Schottky contact in the separation region 10 is higher than the difference in the work function between the drift layer 2 and the source electrode 8 in Schottky contact at the position where the p-type well layer 3B is formed. In addition, the lifetime of the electrons flowing from the source electrode 8 toward the drain electrode 9 in the separation region 10 is lower than the lifetime of the electrons flowing from the source electrode 8 toward the drain electrode 9 at the portion where the p-type well layer 3B is formed.

Even if the n-type separation region 10 is not closed as in the body diode operation structure illustrated in the example in FIG. 5, as illustrated in FIG. 6 as an example, a plurality of p-type well layers 3B may be arranged at intervals narrower than those of the first operation portion which is a normal portion.

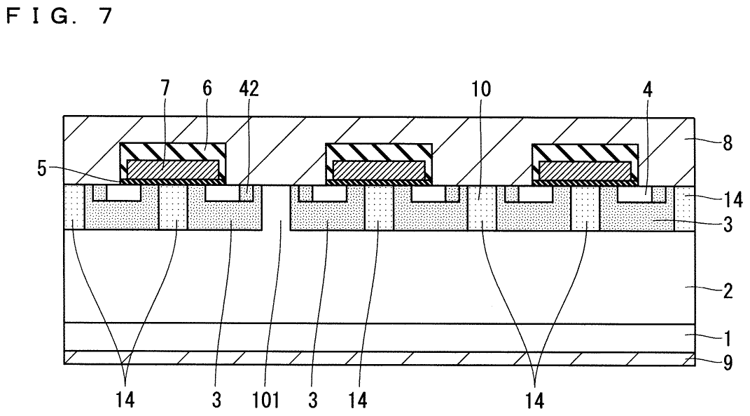

FIG. 7 is a cross-sectional view illustrating another example of the structure of the silicon carbide semiconductor device according to the present preferred embodiment.

As illustrated in FIG. 7 as an example, the SBD built-in MOSFET includes an n-type semiconductor substrate 1, an n-type drift layer 2 formed on an upper surface of the n-type semiconductor substrate 1, a plurality of p-type well layers 3 partially formed on a surface layer of the n-type drift layer 2, a plurality of n-type doped layers 14 partially formed on another surface layer of the n-type drift layer 2, the n-type drift layer 2 being doped with an n-type impurity, an n-type source layer 4 formed on a surface layer of the p-type well layer 3, a p-type contact region 42 partially formed on a surface layer of the p-type well layer 3 and having a higher impurity concentration than the p-type well layer 3, a gate electrode 7 facing an upper surface of the p-type well layer 3 sandwiched between the n-type doped layer 14 and the n-type source layer 4 via a gate insulating film 5, an interlayer insulating film 6 formed to cover an upper surface and a side surface of the gate electrode 7, a source electrode 8 formed to cover the interlayer insulating film 6, the n-type drift layer 2, the p-type well layers 3, the n-type source layers 4, the n-type doped layers 14, and the p-type contact regions 42, and a drain electrode 9 formed on a lower surface of the n-type semiconductor substrate 1. In a region between the p-type well layers 3 at a position not overlapping with the gate electrode 7 in plan view, a region where the n-type doped layer 14 is formed is defined as a separation region 10, and a region where the n-type doped layer 14 is not formed is defined as a separation region 101.

The n-type doped layer 14 is a layer formed by doping the n-type drift layer 2 with n-type impurities (ions and the like), and has an n-type impurity concentration higher than that of the n-type drift layer 2.

In the structure as illustrated in FIG. 7 as an example, since the n-type drift layer 2 has an impurity concentration lower than that of the n-type doped layer 14, a portion where the n-type drift layer 2 is formed (separation region 101) functions as a body diode operation structure.

The change from the structure in which the example is illustrated in FIG. 4 to the structure in which the example is illustrated in FIG. 5, FIG. 6, or FIG. 7 can be performed by only partially changing the mask for forming the p-type well layers 3 or the mask for forming the n-type doped layers 14, and does not involve an increase in manufacturing cost.

In addition, the second operation portion may be formed by locally using a metal having a Schottky barrier height smaller than that of the first operation portion which is a normal portion.

By using these methods, it is possible to locally create a structure in which the rising voltage of the body diode is low.

On the other hand, in order to lower the linear resistance of the body diode, the resistance of the region (contact region) where the p-type well layer 3 and the source electrode 8 in FIG. 4 are in contact with each other may be lowered (the p-type contact region 42 may be provided), or the lifetime may be locally increased.

Similarly to the case where the stacking fault is formed, the body diode operation propagates from the body diode operation structure to a certain range, and thus the size of the body diode operation structure to be formed may be, for example, 10 μm or more and 500 μm or less.

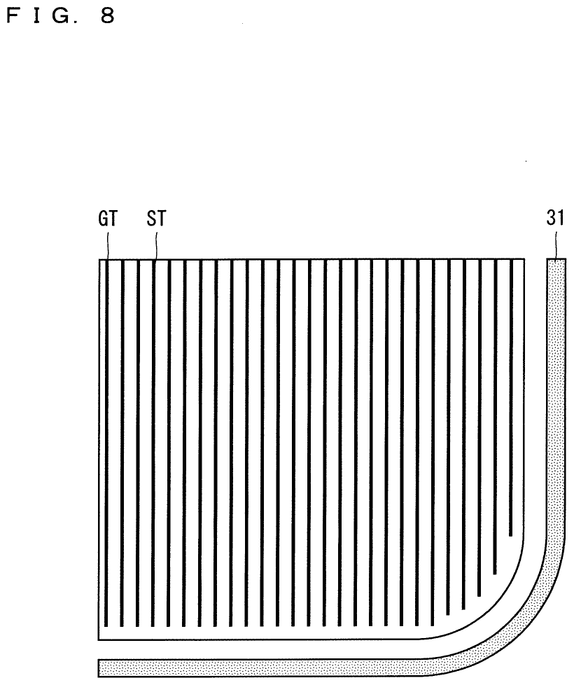

FIG. 8 is a plan view mainly illustrating an example of the configuration of the silicon carbide semiconductor portion in the top view of FIG. 1. In the semiconductor device illustrated in FIG. 8 as an example, in the active region, stripe-shaped gate trenches GT (grooves 102 to be described later) in which transistors are formed and stripe-shaped Schottky wrenches ST (grooves 102 to be described later) are alternately arranged in parallel to each other. A p-type well layer 3 is formed in a termination region around the active region.

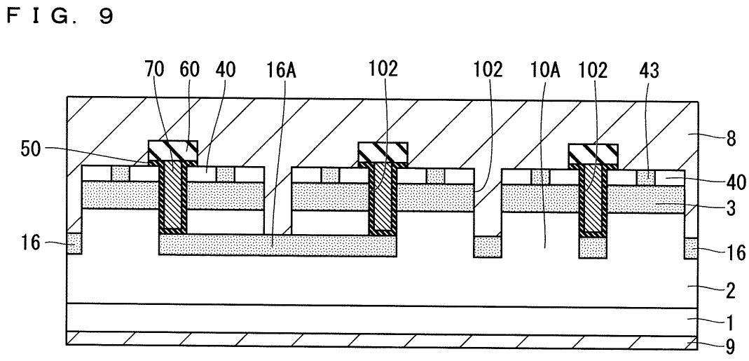

FIG. 9 is a cross-sectional view illustrating another example of the structure of the silicon carbide semiconductor device according to the present preferred embodiment. FIG. 9 illustrates a structure of the SBD built-in MOSFET in the active region of FIG. 8.

As illustrated in FIG. 9 as an example, the SBD built-in MOSFET includes an n-type semiconductor substrate 1, an n-type drift layer 2 formed on an upper surface of the n-type semiconductor substrate 1, a plurality of p-type well layers 3 partially formed on a surface layer of the n-type drift layer 2, a plurality of grooves 102 each formed so as to reach the inside of the n-type drift layer 2 from an upper surface of the p-type well layer 3, a p-type electric field relaxation layer 16 formed on one bottom surface of the groove 102 facing the n-type drift layer 2, an n-type source layer 40 partially formed on a surface layer of the p-type well layer 3 with the groove 102 interposed therebetween, a p-type contact region 43 partially formed on a surface layer of the p-type well layer 3 and having an impurity concentration higher than that of the p-type well layer 3, a gate insulating film 50 formed in contact with a side surface and a bottom surface inside some of the grooves 102, a gate electrode 70 in the groove 102 facing a side surface of the p-type well layer 3 sandwiched between the n-type drift layer 2 and the n-type source layer 40 via the gate insulating film 50, a p-type electric field relaxation layer 16A continuously formed over bottom surfaces of the plurality of grooves 102 in which the gate electrode 70 is formed, the bottom surface facing the n-type drift layer 2, an interlayer insulating film 60 formed to cover an upper surface of the gate electrode 70, a source electrode 8 formed to cover the interlayer insulating films 60, the p-type well layers 3, the n-type source layers 40, the p-type contact regions 43, the electric field relaxation layers 16, and the p-type electric field relaxation layers 16A, and a drain electrode 9 formed on a lower surface of the n-type semiconductor substrate 1. Here, a region between the p-type electric field relaxation layers 16 is defined as a separation region 10A.

The width of the p-type electric field relaxation layer 16A is formed to be wider than the width of the p-type electric field relaxation layer 16. The p-type electric field relaxation layer 16A is formed so as to fill the separation region 10A between the p-type electric field relaxation layers 16, and functions as a body diode operation structure.

A plurality of body diode operation structures may be provided in the semiconductor chip although depending on the size, the number of parallels, or the current value of the semiconductor chip.

On the other hand, in the body diode operation structure, due to its nature, it is inevitable that the body diode current flows even in a normal state (other than when a surge current occurs). Although the body diode current causes an extension of the stacking fault, the body diode operation region created by the provision of the body diode operation structure remains on the order of a few hundred μm in the perimeter. Therefore, even if the stacking fault extends in the region, the variation in the characteristics of the entire semiconductor chip can be sufficiently suppressed.

Although the planar-type SBD built-in MOSFET has been described in FIGS. 4, 5, 6, and 7, as illustrated in FIG. 9 as an example, the structure of the present preferred embodiment is applicable to a trench-type SBD built-in MOSFET.

In the trench-type SBD built-in MOSFET, a p-type electric field relaxation layer 16 is often provided in order to alleviate an electric field applied to the bottom portion of the groove 102, and it is necessary to cope with a body diode formed by the p-type electric field relaxation layer 16 and the n-type drift layer 2 in addition to the body diode formed by the p-type well layer and the n-type drift layer 2 in the planar-type SBD built-in MOSFET.

Although depending on the impurity concentration of the electric field relaxation layer 16 or how the electric field relaxation layer 16 is connected to the source electrode 8, in many cases, the body diode current flows around the body diode formed by the p-type well layer 3 and the n-type drift layer 2.

In the trench-type SBD built-in MOSFET, there are three candidates for the position where the built-in MOSFET is provided. The first is a method of providing a separation region in the p-type well layer 3 between the grooves 102, the second is a method of providing a separation region in the electric field relaxation layer 16, and the third is a method of using a region between the p-type well layer 3 on the side surface of the groove 102 and the electric field relaxation layer 16 as a separation region. However, the third method is not preferable because it is necessary to increase the trench width.

In the first method and the second method, the stacking fault is formed so as to block the separation region, and in the third method, the stacking fault is formed so as to close the space between the electric field relaxation layers 16, so that the body diode operation voltage can be lowered similarly to the planar type.

In contrast, the body diode operation structure having the same policy as that of the planar-type SBD built-in MOSFET can be used. In the case of the first method, the same countermeasure as that of the planar type (see the body diode operation structure of FIG. 9) may be taken. In the case of the second method and the third method, the p-type well layer may be replaced with the electric field relaxation layer 16.

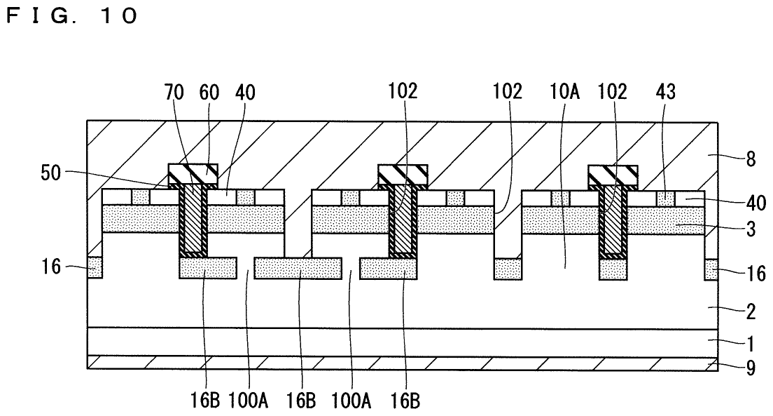

FIG. 10 is a cross-sectional view illustrating another example of the structure of the silicon carbide semiconductor device according to the present preferred embodiment.

As illustrated in FIG. 10 as an example, the SBD built-in MOSFET includes an n-type semiconductor substrate 1, an n-type drift layer 2 formed on an upper surface of the n-type semiconductor substrate 1, a plurality of p-type well layers 3 partially formed on a surface layer of the n-type drift layer 2, a plurality of grooves 102 each formed so as to reach the inside of the n-type drift layer 2 from an upper surface of the p-type well layer 3, a p-type electric field relaxation layer 16 formed on one bottom surface of the groove 102 facing the n-type drift layer 2, an n-type source layer 40 partially formed on a surface layer of the p-type well layer 3 with the groove 102 interposed therebetween, a p-type contact region 43 partially formed on a surface layer of the p-type well layer 3 and having an impurity concentration higher than that of the p-type well layer 3, a gate insulating film 50 formed in contact with a side surface and a bottom surface inside some of the grooves 102, a gate electrode 70 in the groove 102 facing a side surface of the p-type well layer 3 sandwiched between the n-type drift layer 2 and the n-type source layer 40 via the gate insulating film 50, a p-type electric field relaxation layer 16B continuously formed over bottom surfaces of the plurality of grooves 102 in which the gate electrode 70 is formed, the bottom surface facing the n-type drift layer 2, an interlayer insulating film 60 formed to cover an upper surface of the gate electrode 70, a source electrode 8 formed to cover the interlayer insulating films 60, the p-type well layers 3, the n-type source layers 40, the p-type contact regions 43, the electric field relaxation layers 16, and the p-type electric field relaxation layers 16B, and a drain electrode 9 formed on a lower surface of the n-type semiconductor substrate 1.

In the p-type electric field relaxation layers 16B extending over the bottom surfaces of the plurality of grooves 102, an interval (separation region 100A) between the electric field relaxation layers 16B separated from each other is arranged narrower than an interval (separation region 10A) between the plurality of electric field relaxation layers 16. That is, the p-type electric field relaxation layer 16B functions as a body diode operation structure.

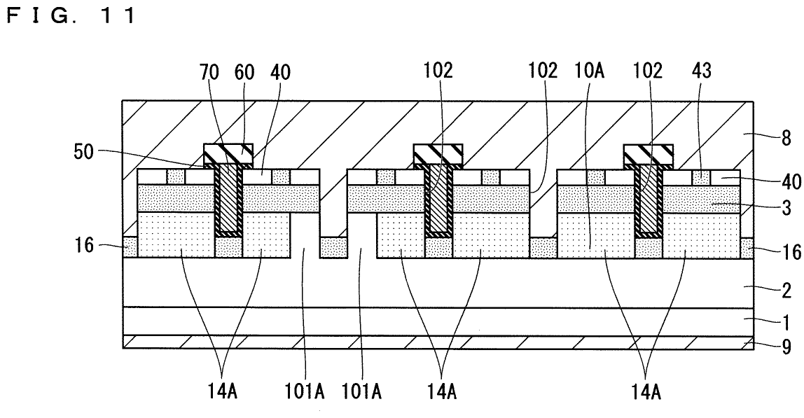

FIG. 11 is a cross-sectional view illustrating another example of the structure of the silicon carbide semiconductor device according to the present preferred embodiment.

As illustrated in FIG. 11 as an example, the SBD built-in MOSFET includes an n-type semiconductor substrate 1, an n-type drift layer 2 formed on an upper surface of the n-type semiconductor substrate 1, a plurality of p-type well layers 3 partially formed on a surface layer of the n-type drift layer 2, a plurality of n-type doped layers 14A partially formed on another surface layer of the n-type drift layer 2, the n-type drift layer 2 being doped with an n-type impurity, a plurality of grooves 102 each formed so as to reach the inside of the n-type drift layer 2 and the inside of the n-type doped layer 14A from an upper surface of the p-type well layer 3, a p-type electric field relaxation layer 16 formed on one bottom surface of the groove 102 facing the n-type drift layer 2 side, an n-type source layer 40 partially formed on a surface layer of the p-type well layer 3 with the groove 102 interposed therebetween, a p-type contact region 43 partially formed on a surface layer of the p-type well layer 3 and having an impurity concentration higher than that of the p-type well layer 3, a gate insulating film 50 formed in contact with a side surface and a bottom surface inside some of the grooves 102, a gate electrode 70 in the groove 102 facing a side surface of the p-type well layer 3 sandwiched between the n-type doped layer 14A and the n-type source layer 40 via the gate insulating film 50, an interlayer insulating film 60 formed to cover an upper surface of the gate electrode 70, a source electrode 8 formed to cover the interlayer insulating films 60, the p-type well layers 3, the n-type source layers 40, the p-type contact regions 43, and the electric field relaxation layers 16, and a drain electrode 9 formed on a lower surface of the n-type semiconductor substrate 1. Here, a region where the n-type doped layer 14A is formed between the p-type electric field relaxation layers 16 is defined as a separation region 10A, and a region where the n-type doped layer 14A is not partially formed between the p-type electric field relaxation layers 16 is defined as a separation region 101A.

The n-type doped layer 14A is a layer formed by doping the n-type drift layer 2 with n-type impurities (ions and the like), and has an n-type impurity concentration higher than that of the n-type drift layer 2.

In the structure as illustrated in FIG. 11 as an example, since the n-type drift layer 2 has an impurity concentration lower than that of the n-type doped layer 14A, a portion where the n-type drift layer 2 is formed (separation region 101A) functions as a body diode operation structure.

### Second Preferred Embodiment

A semiconductor device according to the present preferred embodiment will be described. In the following description, components similar to the components described in the preferred embodiment described above are denoted by the same reference numerals, and detailed description thereof will be omitted as appropriate.

### <Configuration of Semiconductor Device>

In the first preferred embodiment, the first operation portion and the second operation portion having different body diode operation voltages are formed in the SBD built-in MOSFET to lower the body diode operation voltage of the semiconductor chip. On the other hand, the stacking fault may have a body diode operation structure.

Specifically, by selecting only one having a low body diode operation voltage and modularizing it, the variation in the I2t tolerance of the module can be improved.

The variation in the I2t tolerance of the module occurs because the semiconductor chips having different body diode operation voltages are connected in parallel. That is, by inspecting the semiconductor chip used for the module in advance and selecting a semiconductor chip having a low body diode operation voltage, the variation in the I2t tolerance of the module is improved.

In this case, the stacking fault needs to be included in the MOSFET region. Specifically, the stacking fault is present in a planar manner from a certain p-type well layer 3 to a p-type well layer 3 adjacent thereto to close the separation region, so that the body diode operation voltage at the stacking fault portion decreases. In addition, the body diode operation structure described in the first preferred embodiment may or may not be used.

The body diode operation voltage can be determined by measurement at the chip stage. However, in the SBD built-in MOSFET, the body diode is difficult to move due to its nature, and measurement at a high temperature and a high current density is required to confirm the body diode operation voltage.

As a method different from this, a method of selecting the body diode operation voltage based on other electrical characteristics may be used.

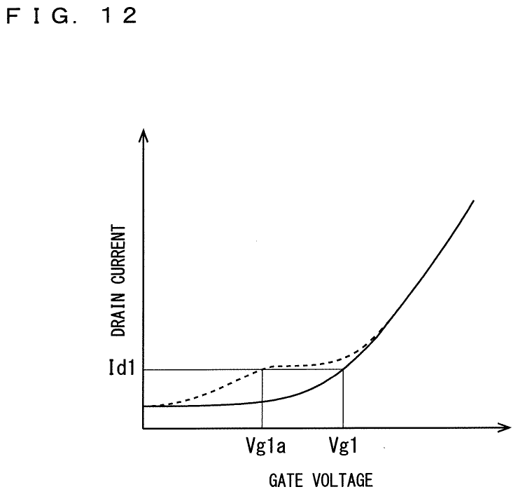

For example, in the case of an SBD built-in MOSFET, a stacking fault that lowers the body diode operation voltage may also affect the electrical characteristics between the gate and the source. Depending on the structure of the p-type well layer of the SBD built-in MOSFET, the gate voltage-drain current characteristics may be tailed as illustrated in FIG. 12 as an example. This is due to the same type of stacking fault as that which lowers the body diode operation voltage. Here, FIG. 12 is a diagram illustrating an example of gate voltage-drain current characteristics of the SBD built-in MOSFET. In FIG. 12, the vertical axis represents the drain current, and the horizontal axis represents the gate voltage. In the example of FIG. 12, the gate voltage Vg1a (see the dotted line) at the drain current Id1 is lower than the gate voltage Vg1 (see the solid line) at the drain current Id1 of the SBD built-in MOSFET without the stacking fault that lowers the operating voltage of the body diode.

Therefore, the gate voltage Vg1 when a certain drain current Id1 flows decreases to Vg1a when the SBD built-in MOSFET includes a stacking fault. As described above, by comparing the gate voltages of the SBD built-in MOSFETs, it is possible to select a semiconductor chip having a low body diode operation voltage.

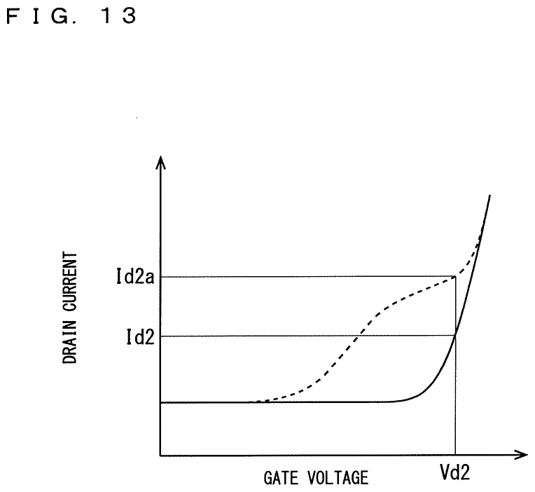

In addition, as illustrated in FIG. 13 as an example, the stacking fault also affects the breakdown voltage characteristics of the SBD built-in MOSFET. The drain current value Id2 (see the solid line) of the SBD built-in MOSFET at a certain drain voltage Vd2 increases to Id2a (see the dotted line) when a stacking fault is included. Therefore, by measuring the drain current, it is possible to select a semiconductor chip having a low body diode operation voltage. Here, FIG. 13 is a diagram illustrating an example of drain voltage-drain current characteristics of the SBD built-in MOSFET. In FIG. 13, the vertical axis represents the drain current, and the horizontal axis represents the drain voltage.

These methods may be determined by a result of a single measurement, or may be determined based on a difference or a ratio of a plurality of measurement results having different currents and voltages.

In addition, as a method different from these methods, it is also possible to inspect a stacking fault at a stage after epitaxial growth. Since the stacking fault has a band gap different from that of 4H—SiC, the in-plane position can be confirmed by a method such as photoluminescence. This may be collated with the position of the semiconductor chip, and the semiconductor chip including the stacking fault may be selected.

The stacking fault of the drift layer 2 is inspected by any of the above methods, and a plurality of specific regions in which the number of stacking faults present per unit region is equal to or less than a predetermined threshold value are specified. Then, after the p-type impurity is ion-implanted into the surface layer of the drift layer 2, the implanted impurity is diffused by heat treatment, and the body diode operation voltage in the specific region is made lower than the body diode operation voltage in the region other than the specific region.

Although the three methods have been described above, one of these methods may be used alone or may be determined by combining a plurality of methods.

As described above, the variation in the I2t tolerance of the module of the power module can be improved by selecting and using a semiconductor chip having a low body diode operation voltage.

### Third Preferred Embodiment

A method of manufacturing a semiconductor device according to the present preferred embodiment will be described. In the following description, components similar to the components described in the preferred embodiment described above are denoted by the same reference numerals, and detailed description thereof will be omitted as appropriate.

### <Method of Manufacturing Silicon Carbide Semiconductor Device (Planar Type)>

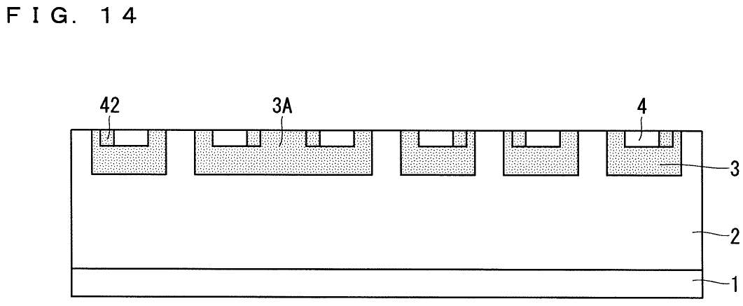

Next, a method of manufacturing an SBD built-in MOSFET (planar type) which is a silicon carbide semiconductor device of the present preferred embodiment will be described with reference to FIGS. 14 to 16. FIGS. 14 to 16 are views illustrating an example of the method of manufacturing a silicon carbide semiconductor device according to the present preferred embodiment.

First, a drift layer 2 made of silicon carbide having an n-type impurity concentration of 1×10¹⁵ cm⁻³ or more and 1×10¹⁷ cm⁻³ or less and a thickness of 5 μm or more and 50 μm or less is epitaxially grown by a chemical vapor deposition (i.e. CVD) method on an upper surface of a semiconductor substrate 1 made of n-type low-resistance silicon carbide in which a plane orientation of a first main surface is a (0001) plane having an off angle and having a polytype of 4H.

Next, an implantation mask is formed by photoresist or the like in a predetermined region of the surface layer of the drift layer 2, and Al (aluminum) which is a p-type impurity is ion-implanted. At this time, the depth of Al ion implantation is about 0.5 μm or more and 3 μm or less which does not exceed the thickness of the drift layer 2. The impurity concentration of ion-implanted Al is in a range of 1× 10¹⁷ cm⁻³ or more and 1×10¹⁹ cm⁻³ or less, and is higher than the impurity concentration of the drift layer 2.

Thereafter, the implantation mask is removed. The region implanted with Al ions by this step becomes the well layer 3 and the well layer 3A in the active region, and becomes the well layer 31 in the termination region.

Next, an implantation mask is formed on the surface layer of the drift layer 2 in the termination region by photoresist or the like, and Al having a p-type impurity concentration is ion-implanted. At this time, the depth of Al ion implantation is about 0.5 μm or more and 3 μm or less which does not exceed the thickness of the drift layer 2. In addition, the impurity concentration of ion-implanted Al is in a range of 1× 10¹⁶ cm⁻³ or more and 1×10¹⁸ cm⁻³ or less, and is higher than the impurity concentration of the drift layer 2 and lower than the impurity concentration of the well layer 3.

Thereafter, the implantation mask is removed. A region into which Al is ion-implanted by this step becomes a JTE region (not illustrated here).

Similarly, Al is ion-implanted into a predetermined region at an impurity concentration in a range of 1×10¹⁶ cm⁻³ or more and 1×10¹⁸ cm⁻³ or less higher than the impurity concentration of the well layer 3, thereby forming the contact region 42.

Next, an implantation mask is formed by a photoresist or the like such that a predetermined portion inside the well layer 3 on the surface layer of the drift layer 2 is opened, and N (nitrogen) which is an n-type impurity is ion-implanted. The ion implantation depth of N is shallower than the thickness of the well layer 3. The impurity concentration of ion-implanted N is in a range of 1×10¹⁸ cm⁻³ or more and 1×10²¹ cm⁻³ or less, and exceeds the p-type impurity concentration of the well layer 3. In the region into which N is implanted in this step, a region indicating n-type becomes the source layer 4.

Next, annealing is performed at a temperature of 1300° C. or higher and 1900° C. or lower for 30 seconds or longer and 1 hour or shorter in an inert gas atmosphere such as argon (Ar) gas by a heat treatment apparatus. By this annealing, the ion-implanted N and Al are electrically activated. FIG. 14 illustrates the configuration of the active region at the stage where the ion implantation is completed in this way.

Next, using a CVD method, a photolithography technique, or the like, a field insulating film (not illustrated here) made of silicon oxide and having a film thickness of 0.5 μm or more and 2 μm or less, which is thicker than the film thickness of the gate insulating film, is formed on the semiconductor layer in the region excluding the active region substantially corresponding to the region where the well layer 3 is formed.

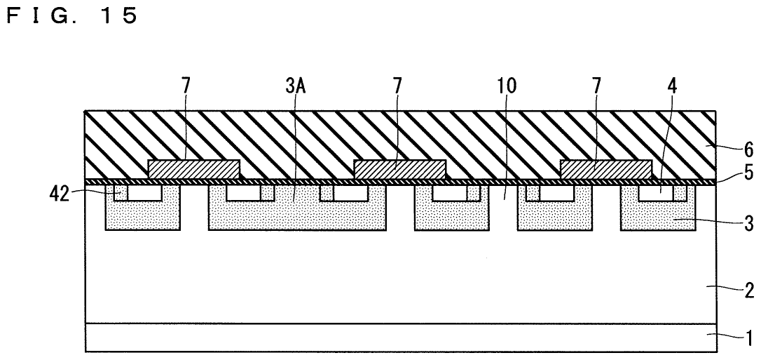

Next, the upper surface of silicon carbide not covered with the field insulating film is thermally oxidized to form a silicon oxide film which is the gate insulating film 5 having a desired thickness. Next, a conductive polycrystalline silicon film is formed on the upper surfaces of the gate insulating film 5 and the field insulating film by a reduced pressure CVD method, and patterned to form the gate electrode 7. Next, the interlayer insulating film 6 having a film thickness larger than that of the gate insulating film and made of silicon oxide is formed by a reduced pressure CVD method. In FIG. 15, the configuration of the active region after the steps up to this stage are illustrated.

Next, an active region contact hole penetrating the interlayer insulating film 6 and the gate insulating film 5 and reaching the source layer 4 in the active region is formed.

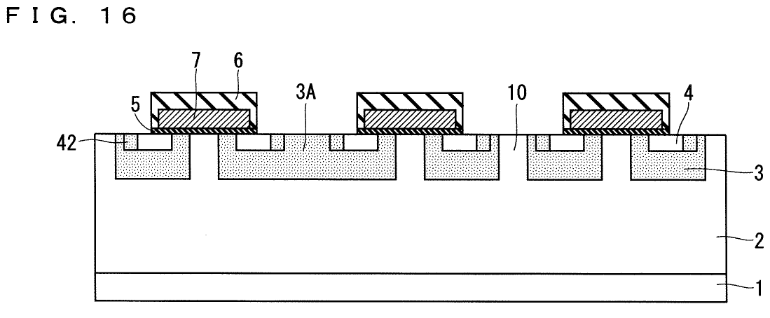

In FIG. 16, the configuration of the active region after the steps up to this stage are illustrated.

Next, a wiring metal such as Al is formed on the upper surface of the semiconductor substrate 1 by a sputtering method or a vapor deposition method, and processed into a predetermined shape by a photolithography technique to form the source electrode 8. In addition, the drain electrode 9 is formed on the lower surface of the semiconductor substrate 1. In this way, the silicon carbide semiconductor device illustrated in FIG. 5 can be manufactured.

Next, the operation of the SBD built-in MOSFET illustrated in FIG. 5 will be described. Here, a semiconductor device in which the semiconductor material is silicon carbide of 4H type will be described as an example. In this case, the diffusion potential of the pn junction is approximately 2 V.

The operation of the SBD built-in MOSFET according to the present preferred embodiment will be briefly described in three states.

A first state is a case where a high voltage is applied to the drain electrode 9 with respect to the source electrode 8 and a positive voltage equal to or higher than a threshold value is applied to the gate electrode 7, and is hereinafter referred to as an “ON state”. In this ON state, an inversion channel is formed in the channel region, and a path through which electrons as carriers flow is formed in a range from the n-type source layer 4 to the drift layer 2 immediately below the gate electrode 7. On the other hand, no current flows between the separation region 10 and the source electrode 8. The electrons flowing from the source electrode 8 into the drain electrode 9 reach the drain electrode 9 from the source electrode 8 via the source layer 4, the channel region, the drift layer 2, and the semiconductor substrate 1 according to an electric field formed by a positive voltage applied to the drain electrode 9. Therefore, by applying a positive voltage to the gate electrode 7, an on-current flows from the drain electrode 9 to the source electrode 8.

At this time, a voltage applied between the source electrode 8 and the drain electrode 9 is referred to as an on-voltage, and a value obtained by dividing the on-voltage by the density of the on-current is referred to as an on-resistance, which are equal to the total resistance in the path through which the electrons flow. Since the product of the on-resistance and the square of the on-current is equal to the energization loss consumed when the MOSFET is energized, the on-resistance is preferably low.

A second state is a case where a high voltage is applied to the drain electrode 9 with respect to the source electrode 8 and a positive voltage equal to or lower than a threshold value is applied to the gate electrode 7, and is hereinafter referred to as an “OFF state”. In this state, since the inversion carrier is not present in the channel region, the on-current does not flow, and the high voltage applied to the load in the ON state is applied between the source electrode 8 and the drain electrode 9 of the MOSFET. Ideally, no current flows between the separation region 10 and the source electrode 8, but since an electric field much higher than that in the “ON state” is applied, a leakage current may be generated. When the leakage current is large, heat generation of the MOSFET is increased, and a module using the MOSFET and the MOSFET may be thermally broken. Therefore, in order to reduce the leakage current, it is preferable to suppress the electric field applied to the Schottky junction to be low.

In a third state, in a state where a low voltage is applied to the drain electrode 9 with respect to the source electrode 8, that is, a counter electromotive voltage is applied to the MOSFET, a reflux current flows from the source electrode 8 toward the drain electrode 9. Hereinafter, this state is referred to as a “reflux state”. In the reflux state, a forward electric field (forward bias) is applied between the separation region 10 and the source electrode 8, and a unipolar current including an electron current flows from the source electrode 8 toward the n-type separation region 10. At this time, the reflux current component of the reflux diode is mainly this unipolar component.

The source electrode 8 and the well layer 3 have the same potential. As a result, a forward bias is also applied to the pn junction between the p-type well layer 3 and the drift layer 2, but the pn junction is formed in parallel with the Schottky junction formed by the n-type separation region 10 and the source electrode 8, and the Schottky junction having a lower threshold voltage is turned on before the pn junction when the state is changed from the OFF state to the reflux state, so that the reflux current flows almost through the Schottky junction and does not flow through the pn junction.

In this way, by building the SBD, it is possible to suppress a forward current which is a bipolar current from flowing through the pn junction even in the reflux state.

When a bipolar current flows through the pn junction and a starting point such as a basal plane dislocation is present at such a position, a stacking fault may be extended and a breakdown voltage of a transistor may be lowered. Specifically, a leakage current is generated when the transistor is in an OFF state, and the element or the circuit may be broken by heat generated by the leakage current.

However, by building the SBD, it is possible to suppress the bipolar current from flowing through the pn junction at the time of reflux, and it is possible to enhance the reliability of the semiconductor device.

### <Method of Manufacturing Silicon Carbide Semiconductor Device (Trench Type)>

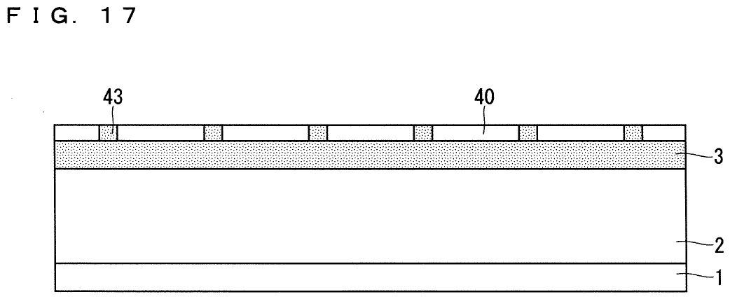

Next, a method of manufacturing an SBD built-in MOSFET (trench type) which is a silicon carbide semiconductor device of the present preferred embodiment will be described with reference to FIGS. 17 to 20. FIGS. 17 to 20 are views illustrating an example of the method of manufacturing a silicon carbide semiconductor device according to the present preferred embodiment.

First, a drift layer 2 made of silicon carbide having an n-type impurity concentration of 1×10¹⁵ cm⁻³ or more and 1×10¹⁷ cm⁻³ or less and a thickness of 5 μm or more and 50 μm or less is epitaxially grown by a chemical vapor deposition (i.e. CVD) method on an upper surface of a semiconductor substrate 1 made of n-type low-resistance silicon carbide in which a plane orientation of a first main surface is a (0001) plane having an off angle and having a polytype of 4H.

Next, an implantation mask is formed by photoresist or the like in a predetermined region of the surface layer of the drift layer 2, and Al (aluminum) which is a p-type impurity is ion-implanted. At this time, the depth of Al ion implantation is about 0.5 μm or more and 3 μm or less which does not exceed the thickness of the drift layer 2. The impurity concentration of ion-implanted Al is in a range of 1× 10¹⁷ cm⁻³ or more and 1×10¹⁹ cm⁻³ or less, and is higher than the impurity concentration of the drift layer 2.

Thereafter, the implantation mask is removed. The region implanted with Al ions by this step becomes the well layer 3 in the active region, and becomes the well layer 31 in the termination region. The well layer 3 may be formed on the drift layer 2 by an epitaxial method.

Next, Al is ion-implanted into a predetermined region of the surface layer portion of the well layer 3 at an impurity concentration in a range of 1×10¹⁶ cm⁻³ or more and 1×10¹⁸ cm⁻³ or less higher than the impurity concentration of the well layer 3, thereby forming the contact region 43.

N as an n-type impurity is ion-implanted into a predetermined region inside the well layer 3 on the surface layer of the drift layer 2. The ion implantation depth of N is shallower than the thickness of the well layer 3. The impurity concentration of ion-implanted N is in a range of 1×10¹⁸ cm⁻³ or more and 1×10²¹ cm⁻³ or less, and exceeds the p-type impurity concentration of the well layer 3. In the region into which N is implanted in this step, a region indicating n-type becomes the source layer 40. In FIG. 17, the configuration of the active region at this stage is illustrated.

Next, the groove 102 is formed at a portion where the source layer 40 is formed, and Al as a p-type impurity is ion-implanted into the bottom portion of the groove 102 to form an electric field relaxation layer 16 at the bottom portion of the groove 102. The impurity concentration of the electric field relaxation layer 16 may be in a range of 1×10¹⁷ cm⁻³ or more and 1×10¹⁹ cm⁻³ or less. For a part of the groove 102 in which the gate electrode 70 is not formed in a later step, the ion implantation amount and the implantation direction (for example, oblique ion implantation) are adjusted so as to be connected to the adjacent electric field relaxation layer, and a p-type electric field relaxation layer 16A extending over the bottom portions of the plurality of grooves 102 is formed.

Here, when the plane orientation of the first main surface of the semiconductor substrate 1 is a (0001) plane having an off angle in the <11-20> direction, the groove 102 in the active region may be formed in parallel to the <11-20> direction. In this way, since the side surfaces on both sides of the groove 102 are not affected by the off direction of the semiconductor substrate 1, it is possible to reduce the variation in the barrier height of the Schottky interface of the groove 102. In addition, since the threshold voltage of the MOSFET in the groove 102 is not affected by the off direction of the semiconductor substrate 1, the variation in the threshold voltage of the MOSFET can be reduced.

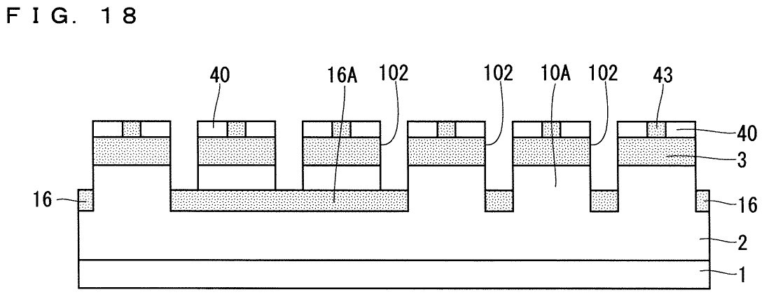

Next, annealing is performed for 30 seconds or more and 1 hour or less at a temperature of 1300° C. or more and 1900° C. or less in an inert gas atmosphere such as Ar gas by a heat treatment apparatus. By this annealing, the ion-implanted N and Al are electrically activated. In FIG. 18, the configuration of the active region at this stage is illustrated.

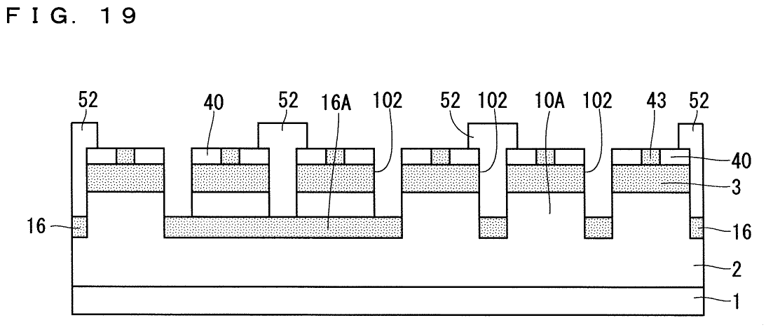

Next, as illustrated in FIG. 19, a protective insulating film 52 such as silicon oxide is filled in some of the grooves 102.

Next, the upper surface of the drift layer 2 that is not covered with the protective insulating film 52 is thermally oxidized to form a silicon oxide film that is the gate insulating film 50 having a desired thickness. Then, a conductive polycrystalline silicon film is formed on the upper surface of the gate insulating film 50 by a reduced pressure CVD method, and patterned to form the gate electrode 70.

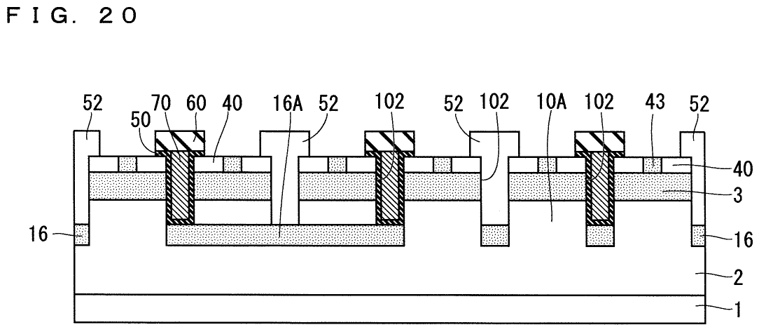

Next, the interlayer insulating film 60 made of silicon oxide and having a film thickness larger than that of the gate insulating film 50 is formed by a reduced pressure CVD method. Next, the interlayer insulating film 60 and the gate insulating film 50 are removed by wet etching so that the source layer 40 in the active region is exposed. FIG. 20 illustrates the configuration of the active region at the stage where the ion implantation is completed in this way.

Next, the protective insulating film 52 in the groove 102 is removed by hydrofluoric acid or the like. The source electrode 8 mainly made of Al is formed so as to cover an upper surface of the drift layer 2. The gate pad 81 and the gate wiring 82 may be formed simultaneously with the source electrode 8.

Further, the drain electrode 9 which is a metal film is formed on the lower surface of the semiconductor substrate 1. In this way, the silicon carbide semiconductor device illustrated in FIG. 9 can be manufactured.

Next, the operation of the SBD built-in MOSFET illustrated in FIG. 9 will be described. The operation of the trench-type SBD built-in MOSFET is similar to that of the planar-type SBD built-in MOSFET in the “ON state” and the “OFF state”.

In addition, in the reflux state, in a state where a low voltage is applied to the drain electrode 9 with respect to the source electrode 8, that is, a counter electromotive voltage is applied to the MOSFET, a reflux current flows from the source electrode 8 toward the drain electrode 9. In the reflux state, a forward electric field (forward bias) is applied to a Schottky junction formed at a contact portion between the drift layer 2 and the source electrode 8, and a unipolar current including an electron current flows from the source electrode 8 toward the n-type drift layer 2. At this time, the reflux current component of the reflux diode is mainly this unipolar component.

The source electrode 8 and the well layer 3 have the same potential. As a result, a forward bias is also applied to the pn junction between the p-type well layer 3 and the drift layer 2, but the pn junction is formed in parallel with the Schottky junction formed by the n-type separation region 10A and the source electrode 8, and the Schottky junction having a lower threshold voltage is turned on before the pn junction when the state is changed from the OFF state to the reflux state, so that the reflux current flows almost through the Schottky junction and does not flow through the pn junction.

In this way, by building the SBD, it is possible to suppress a forward current which is a bipolar current from flowing through the pn junction even in the reflux state.

When a bipolar current flows through the pn junction and a starting point such as a basal plane dislocation is present at such a position, a stacking fault may be extended and a breakdown voltage of a transistor may be lowered. Specifically, a leakage current is generated when the transistor is in an OFF state, and the element or the circuit may be broken by heat generated by the leakage current.

However, by building the SBD, it is possible to suppress the bipolar current from flowing through the pn junction at the time of reflux, and it is possible to enhance the reliability of the semiconductor device.

### Effects Produced by Plurality of Preferred Embodiments Described Above

Next, examples of effects produced by the plurality of preferred embodiments described above will be described. In the following description, the effects will be described based on the specific configurations exemplified in the plurality of preferred embodiments described above, but may be replaced with other specific configurations exemplified in the present specification as long as similar effects are produced. That is, in the following description, for convenience, only one of the associated specific configurations may be described as a representative, but the specific configuration described as a representative may be replaced with another specific configuration associated.

Furthermore, the replacement may be performed across the plurality of preferred embodiments. That is, the same effect may be produced by combining the respective configurations exemplified in different preferred embodiments.

According to the preferred embodiments described above, the semiconductor device includes the drift layer 2 of the first conductivity type (n-type), the well layer 3 (alternatively, the well layer 3A and the well layer 3B) of the second conductivity type (p-type), the n-type source layer 4 (alternatively, the source layer 40), the gate electrode 7 (alternatively, the gate electrode 70), the interlayer insulating film 6 (alternatively, the interlayer insulating film 60), and the source electrode 8. The plurality of p-type well layers 3 are partially formed on the surface layer of the drift layer 2. The n-type source layer 4 is partially formed on the surface layer of each well layer 3. The gate electrode 7 is in contact with the well layer 3 sandwiched between the drift layer 2 and the source layer 4 via a gate insulating film 5 (alternatively, the gate insulating film 50). The interlayer insulating film 6 is provided to cover the gate electrode 7. The source electrode 8 is provided to cover the interlayer insulating film 6, the well layer 3, and the source layer 4. The plurality of body diodes constituted by the well layer 3 and the drift layer 2 at positions not overlapping the gate electrode 7 in plan view include the first operation portion (for example, the body diode in the separation region 10 of FIG. 6) that operates at a first body diode operation voltage and a plurality of second operation portions (for example, the body diode in the separation region 100 of FIG. 6) that operates at a second body diode operation voltage lower than the first body diode operation voltage.

According to such a configuration, by providing a plurality of portions where the body diode operation voltage is lower than the portion where the stacking fault is formed, the body diode operation voltage in the entire semiconductor chip can be effectively lowered, and the decrease in the I2t tolerance can be suppressed. In addition, even if a stacking fault occurs in the first operation portion, the influence on the characteristics of the semiconductor device can be suppressed. In addition, by including the stacking fault in which the body diode operation voltage is low, the body diode operation voltage of the entire semiconductor chip can be lowered to increase the allowable surge current. Therefore, it is possible to increase the I2t tolerance of the semiconductor device and suppress early breakage. When the SBD built-in MOSFET includes a stacking fault, the SBD current path is blocked by the stacking fault at a portion where the stacking fault is present, and the body diode operation voltage at this portion can be lowered. When a bipolar current flows through the pn junction, there is a possibility that a crystal defect such as a stacking fault is expanded. However, since a short time of several hundred ns to several us is assumed as a time of a sequence in a state where a surge current flows, expansion of a crystal defect such as a stacking fault is unlikely to occur.

Even in a case where another configuration exemplified in the present specification is appropriately added to the above configuration, that is, even in a case where another configuration not mentioned as the above configuration in the present specification is appropriately added, a similar effect can be generated.

In addition, according to the preferred embodiments described above, the width between the well layers 3 in the first operation portion is wider than the width between the well layers 3B in the second operation portion. According to such a configuration, since the separation region 100 formed by the plurality of p-type well layers 3B is narrower than the separation region 10 and functions as a body diode operation structure, the body diode operation voltage in the entire semiconductor chip can be effectively lowered, and the decrease in the I2t tolerance can be suppressed.

In addition, according to the preferred embodiments described above, the width of the well layer 3 in the first operation portion is narrower than the width of the well layer 3A in the second operation portion. According to such a configuration, since the p-type well layer 3A is formed so as to fill the separation region 10 between the p-type well layers 3 and functions as a body diode operation structure, the body diode operation voltage in the entire semiconductor chip can be effectively lowered, and the decrease in the I2t tolerance can be suppressed.

In addition, according to the preferred embodiments described above, the semiconductor device includes the groove 102 formed to reach a position deeper than the well layer 3 from the upper surface of the source layer 40, and the electric field relaxation layer 16 (alternatively, the electric field relaxation layer 16A and the electric field relaxation layer 16B) formed at the bottom portion of the groove 102. The gate insulating film 50 is formed in the groove 102 so as to cover the side surface of the well layer 3 sandwiched between the source layer 40 and the drift layer 2. In addition, the gate electrode 70 is formed to be surrounded by the gate insulating film 50 in the groove 102. According to such a configuration, the body diode operation voltage in the entire trench-type semiconductor chip can be effectively lowered, and the decrease in the I2t tolerance can be suppressed.

In addition, according to the preferred embodiments described above, the width between the electric field relaxation layers 16 in the first operation portion is wider than the width between the electric field relaxation layers 16B in the second operation portion. According to such a configuration, since the p-type electric field relaxation layer 16B functions as a body diode operation structure, the body diode operation voltage in the entire semiconductor chip can be effectively lowered, and the decrease in the I2t tolerance can be suppressed.

In addition, according to the preferred embodiments described above, the width of the electric field relaxation layer 16 in the first operation portion is narrower than the width of the electric field relaxation layer 16A in the second operation portion. According to such a configuration, the p-type electric field relaxation layer 16A is formed so as to fill the separation region 10A between the p-type electric field relaxation layers 16 and functions as a body diode operation structure, the body diode operation voltage in the entire semiconductor chip can be effectively lowered, and the decrease in the I2t tolerance can be suppressed.

According to the preferred embodiments described above, the impurity concentration of the drift layer 2 in the first operation portion is higher than the impurity concentration of the drift layer 2 in the second operation portion. According to such a configuration, since the n-type drift layer 2 has an impurity concentration lower than that of the n-type doped layer 14, a portion where the n-type drift layer 2 is formed functions as a body diode operation structure, so that the body diode operation voltage in the entire semiconductor chip can be effectively lowered, and the decrease in the I2t tolerance can be suppressed.

Further, according to the preferred embodiments described above, at least one of the first operation portion and the second operation portion includes a stacking fault having a linear shape in plan view. The stacking fault density in the second operation portion is lower than the stacking fault density in the first operation portion (the second operation portion may not include the stacking fault). According to such a configuration, the stacking fault is present in a planar manner and functions as the body diode operation structure by closing the separation region, so that the body diode operation voltage in the entire semiconductor chip can be effectively lowered, and the decrease in the I2t tolerance can be suppressed.

According to the preferred embodiments described above, the semiconductor device includes the p-type contact region 42 (alternatively, the contact region 43) partially formed on the surface layer of the well layer 3. The impurity concentration of the contact region 42 is higher than the impurity concentration of the well layer 3, and the contact resistance of the contact region 42 of the first operation portion is higher than the contact resistance of the contact region 42 of the second operation portion. According to such a configuration, the body diode operation voltage in the entire semiconductor chip can be effectively lowered, and the decrease in the I2t tolerance can be suppressed.

In addition, according to the preferred embodiments described above, the difference in the work function between the drift layer 2 and the source electrode 8 in Schottky contact in the first operation portion is higher than the difference in the work function between the drift layer 2 and the source electrode 8 in Schottky contact in the second operation portion. According to such a configuration, the body diode operation voltage in the entire semiconductor chip can be effectively lowered, and the decrease in the I2t tolerance can be suppressed.

According to the preferred embodiments described above, the lifetime of the electrons flowing from the source electrode 8 toward the drain electrode 9 provided on the lower surface side of the drift layer 2 on the opposite side of the source electrode 8 in the first operation portion is lower than the lifetime of the electrons flowing from the source electrode 8 toward the drain electrode 9 in the second operation portion. According to such a configuration, the body diode operation voltage in the entire semiconductor chip can be effectively lowered, and the decrease in the I2t tolerance can be suppressed.

According to the preferred embodiments described above, in the method of manufacturing a semiconductor device, the n-type drift layer 2 is formed by epitaxial growth. Then, the stacking fault of the drift layer 2 is inspected to specify a plurality of specific regions in which the number of stacking faults present per unit region is equal to or less than a predetermined threshold value. Then, the p-type impurity is ion-implanted into the surface layer of the drift layer 2. Then, the implanted impurity is diffused by heat treatment to make the body diode operation voltage in the plurality of specific regions lower than the body diode operation voltage in regions other than the specific regions.

According to such a configuration, by providing a plurality of portions where the body diode operation voltage is lower than the portion where the stacking fault is formed, the body diode operation voltage in the entire semiconductor chip can be effectively lowered, and the decrease in the I2t tolerance can be suppressed.

Note that, in a case where there is no particular limitation, the order in which each processing is performed can be changed.

Even in a case where another configuration exemplified in the present specification is appropriately added to the above configuration, that is, even in a case where another configuration not mentioned as the above configuration in the present specification is appropriately added, a similar effect can be generated.

In addition, according to the preferred embodiments described above, the stacking fault is inspected by an electrical characteristic inspection or a photoluminescence method. According to such a configuration, it is possible to effectively find a specific region in which the number of stacking faults is equal to or less than a predetermined threshold value.

### Fourth Preferred Embodiment

In the present preferred embodiment, the semiconductor devices according to the first to third preferred embodiments described above are applied to a power conversion apparatus. Although the present preferred embodiment is not limited to a specific power conversion apparatus, a case where the semiconductor device is applied to a three-phase inverter will be described below as a fourth preferred embodiment.

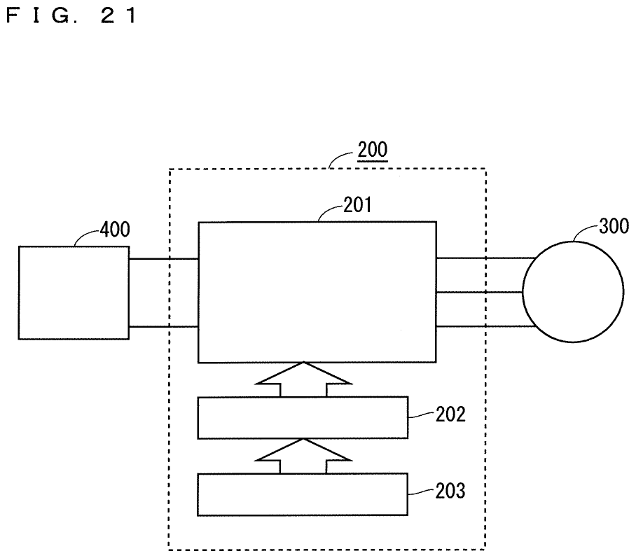

FIG. 21 is a block diagram illustrating a configuration of a power conversion system to which the power conversion apparatus according to the present preferred embodiment is applied.

The power conversion system illustrated in FIG. 21 includes a power supply 400, a power conversion apparatus 200, and a load 300. The power supply 400 is a DC power supply, and supplies DC power to the power conversion apparatus 200. The power supply 400 can include various components, and can include, for example, a DC system, a solar cell, and a storage battery, or may include a rectifier circuit or an AC/DC converter connected to an AC system. In addition, the power supply 400 may be configured by a DC/DC converter that converts DC power output from the DC system into predetermined power.

The power conversion apparatus 200 is a three-phase inverter connected between the power supply 400 and the load 300, converts DC power supplied from the power supply 400 into AC power, and supplies the AC power to the load 300. As illustrated in FIG. 21, the power conversion apparatus 200 includes a main conversion circuit 201 that converts DC power into AC power and outputs the AC power, a drive circuit 202 that outputs a drive signal for driving each switching element of the main conversion circuit 201, and a control circuit 203 that outputs a control signal for controlling the drive circuit 202 to the drive circuit 202.

The load 300 is a three-phase electric motor driven by the AC power supplied from the power conversion apparatus 200. The load 300 is not limited to a specific application, but is an electric motor mounted on various electric devices, and is used as, for example, an electric motor for a hybrid vehicle, an electric vehicle, a railway vehicle, an elevator, or an air conditioner.

Hereinafter, details of the power conversion apparatus 200 will be described. The main conversion circuit 201 includes a switching element and a reflux diode (not illustrated), converts DC power supplied from the power supply 400 into AC power by switching of the switching element, and supplies the AC power to the load 300. Although there are various specific circuit configurations of the main conversion circuit 201, the main conversion circuit 201 according to the present preferred embodiment is a two-level three-phase full bridge circuit, and can include six switching elements and six reflux diodes antiparallel to the respective switching elements. The semiconductor device according to any one of the above-described preferred embodiments is applied to each switching element of the main conversion circuit 201. The six switching elements are connected in series for every two switching elements to constitute upper and lower arms, and each of the upper and lower arms constitutes each phase (U-phase, V-phase, W-phase) of the full bridge circuit. The output terminals of the upper and lower arms, that is, the three output terminals of the main conversion circuit 201 are connected to the load 300.

The drive circuit 202 generates a drive signal for driving the switching element of the main conversion circuit 201, and supplies the drive signal to the control electrode of the switching element of the main conversion circuit 201. Specifically, in accordance with a control signal from the control circuit 203 to be described later, a drive signal for turning on the switching element and a drive signal for turning off the switching element are output to the control electrode of each switching element. When the switching element is maintained in the ON state, the drive signal is a voltage signal (ON signal) equal to or higher than the threshold voltage of the switching element, and when the switching element is maintained in the OFF state, the drive signal is a voltage signal (OFF signal) equal to or lower than the threshold voltage of the switching element.

The control circuit 203 controls the switching element of the main conversion circuit 201 so that desired power is supplied to the load 300. Specifically, a time (ON time) during which each switching element of the main conversion circuit 201 is to be turned on is calculated based on the power to be supplied to the load 300. For example, the main conversion circuit 201 can be controlled by PWM control that modulates the ON time of the switching element according to the voltage to be output. Then, a control command (control signal) is output to the drive circuit 202 so that an ON signal is output to the switching element to be turned on at each time point, and an OFF signal is output to the switching element to be turned off at each time point. The drive circuit 202 outputs an ON signal or an OFF signal as a drive signal to the control electrode of each switching element according to the control signal.

In the power conversion apparatus according to the present preferred embodiment, since the semiconductor devices according to the first to third preferred embodiments are applied as the switching elements of the main conversion circuit 201, it is possible to improve reliability.

In the present preferred embodiment, an example in which the present technology is applied to a two-level three-phase inverter has been described, but the present technology is not limited thereto, and can be applied to various power conversion apparatus. In the present preferred embodiment, the two-level power conversion apparatus is used, but a three-level or multi-level power conversion apparatus may be used, or the present technology may be applied to a single-phase inverter in a case where power is supplied to a single-phase load. Furthermore, in a case where power is supplied to a DC load or the like, the present technology can also be applied to a DC/DC converter or an AC/DC converter.

Furthermore, the power conversion apparatus to which the present technology is applied is not limited to the case where the load described above is an electric motor, and can be used as, for example, a power supply device of an electric discharge machine, a laser beam machine, an induction heating cooker, or a non-contact power feeding system, and can also be used as a power conditioner of a solar power generation system, a power storage system, or the like.

### Modifications of Plurality of Preferred Embodiments Described Above

In the plurality of preferred embodiments described above, a material quality, a material, a dimension, a shape, a relative arrangement relationship, an implementation condition, or the like of each component may also be described, but these are one example in all aspects and are not restrictive.

Therefore, innumerable modifications and equivalents in which no examples are shown are assumed within the scope of the technology disclosed in the present specification. For example, a case where at least one component is modified, added, or omitted, and a case where at least one component in at least one preferred embodiment is extracted and combined with a component in another preferred embodiment are included.

In addition, in at least one preferred embodiment described above, in a case where a material name or the like is described without being particularly specified, unless there is a contradiction, the material includes other additives, for example, an alloy or the like.

In addition, unless there is a contradiction, when it is described in the above-described preferred embodiments that “one” component is provided, “one or more” components may be provided.

Furthermore, each component in the preferred embodiments described above is a conceptual unit, and the scope of the technology disclosed in the present specification includes a case where one component includes a plurality of structures, a case where one component corresponds to a part of a certain structure, and a case where a plurality of components is included in one structure.

In addition, each component in the preferred embodiments described above includes a structure having another structure or shape as long as the same function is exhibited.

In addition, the description in the present specification herein is referred to for all purposes relating to the present technology, and none of them is recognized as conventional technology.

Hereinafter, various aspects of the present disclosure will be collectively described as Appendices.

### Appendix 1

A semiconductor device comprising:
a drift layer of a first conductivity type;
a plurality of well layers of a second conductivity type partially formed on a surface layer of the drift layer;
a source layer of a first conductivity type partially formed on a surface layer of each of the well layers;
a gate electrode that is in contact with the well layer sandwiched between the drift layer and the source layer via a gate insulating film;
an interlayer insulating film provided to cover the gate electrode; and
a source electrode provided to cover the interlayer insulating film, the well layer, and the source layer, wherein
a plurality of body diodes constituted by the well layer and the drift layer at positions not overlapping with the gate electrode in plan view include a first operation portion that operates at a first body diode operation voltage and a plurality of second operation portions that operate at a second body diode operation voltage lower than the first body diode operation voltage.

### Appendix 2

The semiconductor device according to Appendix 1, wherein
a width of the well layer in the first operation portion is narrower than a width of the well layer in the second operation portion.

### Appendix 3

The semiconductor device according to Appendix 1 or 2, wherein
a width between the well layers in the first operation portion is wider than a width between the well layers in the second operation portion.

### Appendix 4

The semiconductor device according to Appendix 1, further comprising:
a groove formed to reach a position deeper than the well layer from an upper surface of the source layer; and
an electric field relaxation layer formed at a bottom portion of the groove, wherein
the gate insulating film is formed in the groove so as to cover a side surface of the well layer sandwiched between the source layer and the drift layer, and
the gate electrode is formed to be surrounded by the gate insulating film in the groove.

### Appendix 5

The semiconductor device according to Appendix 4, wherein
a width between the electric field relaxation layers in the first operation portion is wider than a width between the electric field relaxation layers in the second operation portion.

### Appendix 6

The semiconductor device according to Appendix 4 or 5, wherein
a width between the electric field relaxation layers in the first operation portion is wider than a width between the electric field relaxation layers in the second operation portion.

### Appendix 7

The semiconductor device according to any one of Appendixes 1 to 6, wherein
an impurity concentration of the drift layer in the first operation portion is higher than an impurity concentration of the drift layer in the second operation portion.

### Appendix 8

The semiconductor device according to any one of Appendixes 1 to 7, wherein
at least one of the first operation portion and the second operation portion includes a stacking fault having a linear shape in plan view, and
a stacking fault density in the second operation portion is lower than a stacking fault density in the first operation portion.

### Appendix 9

The semiconductor device according to any one of Appendixes 1 to 8, further comprising a contact region of a second conductivity type partially formed on a surface layer of the well layer, wherein
an impurity concentration of the contact region is higher than an impurity concentration of the well layer, and
a contact resistance of the contact region of the first operation portion is higher than a contact resistance of the contact region of the second operation portion.

### Appendix 10

The semiconductor device according to any one of Appendixes 1 to 9, wherein
a difference in a work function between the drift layer and the source electrode in Schottky contact in the first operation portion is higher than a difference in a work function between the drift layer and the source electrode in Schottky contact in the second operation portion.

### Appendix 11

The semiconductor device according to any one of Appendixes 1 to 10, wherein
a lifetime of electrons flowing from the source electrode toward a drain electrode provided on a lower surface side of the drift layer opposite to the source electrode in the first operation portion is lower than a lifetime of electrons flowing from the source electrode toward the drain electrode in the second operation portion.

### Appendix 12

A method of manufacturing a semiconductor device, the method comprising:
forming a drift layer of a first conductivity type by epitaxial growth;
inspecting a stacking fault in the drift layer to specify a plurality of specific regions in which the number of stacking faults present per unit region is equal to or less than a predetermined threshold value;
ion-implanting an impurity of a second conductivity type into a surface layer of the drift layer; and
diffusing the implanted impurity by heat treatment to make a body diode operation voltage in the plurality of specific regions lower than a body diode operation voltage in regions other than the specific regions.

### Appendix 13

The method of manufacturing a semiconductor device according to Appendix 12, wherein
the stacking fault is inspected by an electrical characteristic inspection or a photoluminescence method.

### Appendix 14

A power conversion apparatus comprising:
a main conversion circuit that includes the semiconductor device according to any one of Appendixes 1, 2, 4, and 5, and converts and outputs input power;
a drive circuit that outputs a drive signal for driving the semiconductor device to the semiconductor device; and
a control circuit that outputs a control signal for controlling the drive circuit to the drive circuit.

While the disclosure has been shown and described in detail, the foregoing description is in all aspects illustrative and not restrictive. It is therefore understood that numerous modifications and variations can be devised.

What is claimed is:

1. A semiconductor device comprising:
a drift layer of a first conductivity type;
a plurality of well layers of a second conductivity type partially formed on a surface layer of the drift layer;
a source layer of a first conductivity type partially formed on a surface layer of each of the well layers;
a gate electrode that is in contact with the well layer sandwiched between the drift layer and the source layer via a gate insulating film;
an interlayer insulating film provided to cover the gate electrode; and
a source electrode provided to cover the interlayer insulating film, the well layer, and the source layer, wherein
a plurality of body diodes constituted by the well layer and the drift layer at positions not overlapping with the gate electrode in plan view include a first operation portion that operates at a first body diode operation voltage and a plurality of second operation portions that operate at a second body diode operation voltage lower than the first body diode operation voltage.

2. The semiconductor device according to claim 1, wherein
a width of the well layer in the first operation portion is narrower than a width of the well layer in the second operation portion.

3. The semiconductor device according to claim 1, wherein
a width between the well layers in the first operation portion is wider than a width between the well layers in the second operation portion.

4. The semiconductor device according to claim 1, further comprising:
a groove formed to reach a position deeper than the well layer from an upper surface of the source layer; and
an electric field relaxation layer formed at a bottom portion of the groove, wherein
the gate insulating film is formed in the groove so as to cover a side surface of the well layer sandwiched between the source layer and the drift layer, and
the gate electrode is formed to be surrounded by the gate insulating film in the groove.

5. The semiconductor device according to claim 4, wherein
a width between the electric field relaxation layers in the first operation portion is wider than a width between the electric field relaxation layers in the second operation portion.

6. The semiconductor device according to claim 4, wherein
a width of the electric field relaxation layer in the first operation portion is narrower than a width of the electric field relaxation layer in the second operation portion.

7. The semiconductor device according to claim 1, wherein
an impurity concentration of the drift layer in the first operation portion is higher than an impurity concentration of the drift layer in the second operation portion.

8. The semiconductor device according to claim 1, wherein
at least one of the first operation portion and the second operation portion includes a stacking fault having a linear shape in plan view, and
a stacking fault density in the second operation portion is lower than a stacking fault density in the first operation portion.

9. The semiconductor device according to claim 1, further comprising a contact region of a second conductivity type partially formed on a surface layer of the well layer, wherein
an impurity concentration of the contact region is higher than an impurity concentration of the well layer, and
a contact resistance of the contact region of the first operation portion is higher than a contact resistance of the contact region of the second operation portion.

10. The semiconductor device according to claim 1, wherein
a difference in a work function between the drift layer and the source electrode in Schottky contact in the first operation portion is higher than a difference in a work function between the drift layer and the source electrode in Schottky contact in the second operation portion.

11. The semiconductor device according to claim 1, wherein
a lifetime of electrons flowing from the source electrode toward a drain electrode provided on a lower surface side of the drift layer opposite to the source electrode in the first operation portion is lower than a lifetime of electrons flowing from the source electrode toward the drain electrode in the second operation portion.

12. A method of manufacturing a semiconductor device, the method comprising:
forming a drift layer of a first conductivity type by epitaxial growth;
inspecting a stacking fault in the drift layer to specify a plurality of specific regions in which the number of stacking faults present per unit region is equal to or less than a predetermined threshold value;
ion-implanting an impurity of a second conductivity type into a surface layer of the drift layer; and
diffusing the implanted impurity by heat treatment to make a body diode operation voltage in the plurality of specific regions lower than a body diode operation voltage in regions other than the specific regions.

13. The method of manufacturing a semiconductor device according to claim 12, wherein
the stacking fault is inspected by an electrical characteristic inspection or a photoluminescence method.

14. A power conversion apparatus comprising:
a main conversion circuit that includes the semiconductor device according to claim 1, and converts and outputs input power;
a drive circuit that outputs a drive signal for driving the semiconductor device to the semiconductor device; and
a control circuit that outputs a control signal for controlling the drive circuit to the drive circuit.
